(19) United States
(12) Patent Application Publication
(10) Pub. No.: US 2009/0081821 A1
(43) Pub. Date: Mar. 26, 2009

(54) METHOD OF MANUFACTURING SEMICONDUCTOR LIGHT-EMITTING ELEMENT

(75) Inventor: Masami Aihara, Tokyo (JP)

Correspondence Address: BRINKS HOFER GILSON & LIONE, P.O. BOX 10395, CHICAGO, IL, 60610, US

(73) Assignee: Alps Electric Co., Ltd, Tokyo (JP)

(21) Appl. No.: 12/275,823

(22) Filed: Nov. 21, 2008

(30) Foreign Application Priority Data
May 23, 2006 (JP) 2006-142935
May 22, 2007 (JP) PCT/JP2007/060452

(51) Int. Cl. H01L 33/00

(52) U.S. Cl. 438/42; 257/E33.006

(57) ABSTRACT

A semiconductor layer is provided on a surface of a sapphire substrate, the sapphire substrate having smooth surfaces. A support substrate is mounted on an electrode formation surface of the semiconductor layer. A surface portion of the semiconductor layer is melted, and the sapphire substrate is separated from the semiconductor layer at an interface between the sapphire substrate and the semiconductor layer, thereby exposing the semiconductor layer. While the surface portion of the exposed semiconductor layer is melted, the holding substrate with projections/depressions or stripe grooves is pressed against the surface portion of the semiconductor layer, so that the projections/depressions or stripe grooves formed in the holding substrate are transferred onto the surface portion of the semiconductor layer. The support substrate is separated from the semiconductor layer at an interface between the semiconductor layer and the support substrate.

### RELATED APPLICATIONS

This application claims benefit of the Japanese Patent Application No. 2006-142935 filed on May 23, 2006, which is hereby incorporated by reference.

### BACKGROUND

1. Field of the Invention

The present invention relates to a method of manufacturing a semiconductor light-emitting element, and more particularly to a method of easily and inexpensively manufacturing a flip chip semiconductor light-emitting element having a semiconductor layer with high crystal quality and providing high light extraction efficiency.

2. Description of the Related Art

Hitherto, a flip chip semiconductor light-emitting element has been known, the semiconductor light-emitting element having a sapphire substrate and a GaN-based semiconductor layer provided on the sapphire substrate. In such a semiconductor light-emitting element, the sapphire substrate has a refractive index of about 1.8, and the GaN-based semiconductor layer has a refractive index of about 2.5. Hence, a waveguide is formed inside the GaN-based semiconductor layer, resulting in a problem that light emitted from the GaN-based semiconductor layer is not efficiently output to the outside.

As means for solving the problem, heretofore, a technique for forming a texture processed layer having a surface with very small projections/depressions on a semiconductor-layer formation surface of a sapphire substrate (for example, see Japanese Unexamined Patent Application Publication No. 2004-193619), and a technique for forming very small projections/depressions or stripe grooves directly in a semiconductor-layer formation surface of a sapphire substrate (for example, see Japanese Unexamined Patent Application Publication No. 2005-64492) have been suggested.

With these techniques, light emitted from the GaN-based semiconductor layer is scattered by the very small projection/depression structure formed in an interface between the sapphire substrate and the GaN-based semiconductor layer. Accordingly, light entrapment inside the GaN-based semiconductor layer as a result of reflection is reduced, and light extraction efficiency can be enhanced.

However, in the techniques described in the publications, the very small projections/depressions are formed on the sapphire substrate serving as a ground of the GaN-based semiconductor layer, resulting in problems that crystal quality of the GaN-based semiconductor layer formed in the surface with the projections/depressions is deteriorated, and that internal quantum efficiency originally owned by the semiconductor layer is reduced. Also, the internal quantum efficiency originally owned by the semiconductor layer is seriously affected by a small variation in surface condition of the sapphire substrate. Owing to this, it is difficult to constantly manufacture a high-quality semiconductor light-emitting element. Further, the sapphire substrate has difficulty in processing. When the projections/depressions or the stripe grooves are to be directly formed in the sapphire substrate, it is difficult to enhance productivity of the sapphire substrate, and productivity of the semiconductor light-emitting element.

### BRIEF SUMMARY

In light of the above situations, the present invention provides a method of easily and inexpensively manufacturing a flip chip semiconductor light-emitting element having a semiconductor layer with high crystal quality and providing high light extraction efficiency.

To overcome the above-described problems, the present invention provides a first configuration including the steps of forming a semiconductor layer on a surface of a sapphire substrate, the sapphire substrate having smooth surfaces; mounting a support substrate on the semiconductor layer, the support substrate temporarily supporting the semiconductor layer; melting a surface portion of the semiconductor layer and separating the sapphire substrate from the semiconductor layer at an interface between the sapphire substrate and the semiconductor layer, thereby exposing the semiconductor layer; while the exposed surface portion of the semiconductor layer is melted, pressing the holding substrate against the surface portion of the semiconductor layer, the holding substrate being transparent to light emitted from the semiconductor layer, thereby transferring projections/depressions or stripe grooves formed in the holding substrate onto the surface portion of the semiconductor layer; and separating the support substrate from the semiconductor layer at an interface between the semiconductor layer and the support substrate.

As described above, while the surface portion is melted, the holding substrate with the projections/depressions or stripe grooves is pressed against the surface portion of the semiconductor layer, so that the projections/depressions or stripe grooves for light scattering are transferred onto the interface between the semiconductor layer and the holding substrate. Hence, the crystal quality of the semiconductor layer is not adversely affected, and a high-quality semiconductor light-emitting element can be constantly manufactured.

Also, in view of the method of manufacturing the semiconductor light-emitting element according to the first configuration, the present invention may provide a second configuration. In the second configuration, the holding substrate may be an amorphous inorganic dielectric.

An amorphous inorganic dielectric such as quartz or glass is processed more easily as compared with sapphire. Hence, productivity of the holding substrate and productivity of the semiconductor light-emitting element can be enhanced as compared with the case of using the sapphire substrate.

Further, in view of the method of manufacturing the semiconductor light-emitting element according to the first or second configuration, the present invention may provide a third configuration. In the third configuration, the pressing of the holding substrate against the semiconductor layer may be performed in vacuum.

When the pressing is performed in vacuum, air is hardly mixed into an area between the semiconductor layer and the holding substrate. Production of defectives and variation in quality can be prevented, and productivity of a high-quality semiconductor light-emitting element can be enhanced.

### BRIEF DESCRIPTION OF THE DRAWINGS

FIG. 1 is a cross-sectional view showing a semiconductor light-emitting element according to an embodiment of the present invention;

FIG. 2 is a flowchart showing a manufacturing procedure of the semiconductor light-emitting element according to an embodiment of the present invention; and

FIG. 3 is a table showing effects of semiconductor light-emitting elements according to an example of the present invention as compared with semiconductor light-emitting elements without projections/depressions or grooves.

### DETAILED DESCRIPTION OF THE DRAWINGS AND THE PRESENTLY PREFERRED EMBODIMENTS

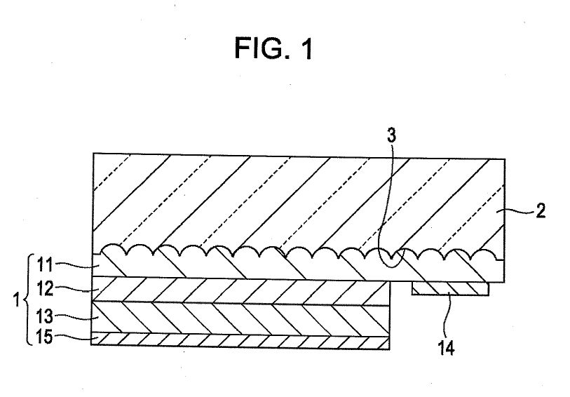

First, an exemplary semiconductor light-emitting element to be manufactured by an embodiment of the present invention is described with reference to FIG. 1. FIG. 1 is a cross-sectional view showing the semiconductor light-emitting element to be manufactured by the embodiment of the present invention.

Referring to the figure, the semiconductor light-emitting element of this embodiment includes a semiconductor layer 1 and a holding substrate 2 provided on a light extraction surface of the semiconductor layer 1. Very small projections/depressions or stripe grooves 3 are formed in an inner surface (semiconductor layer 1 side) of the holding substrate 2. The depth and width of the projections/depressions or grooves 3 are equivalent to or slightly larger than a wavelength of light emitted from the semiconductor layer 1. Thus, the light can be scattered by the inner surface of the holding substrate 2.

Referring to FIG. 1, the semiconductor layer 1 includes an n-GaN layer 11, a light-emitting layer 12, a p-GaN layer 13, an n-electrode 14 provided on the n-GaN layer 11, and a p-electrode 15 provided on the p-GaN layer 13. The layer structure of the layers of the semiconductor layer 1 is not limited to the structure shown in FIG. 1, and a semiconductor having any known layer structure may be formed. Also, the layer technique of the semiconductor layer 1 is not a primary part of the present invention and is known. Thus, the layer technique is not described in the specification.

The holding substrate 2 protects the semiconductor layer 1. The holding substrate 2 is transparent to the light emitted from the semiconductor layer 1. The holding substrate 2 is made of a material with a proper hardness. The material of forming the holding substrate 2 may be more preferably glass or quartz because glass or quartz has high transparency and exhibits high processability as compared with processability of single crystal sapphire. The very small projections/depressions or stripe grooves 3 may be formed by etching using photolithography.

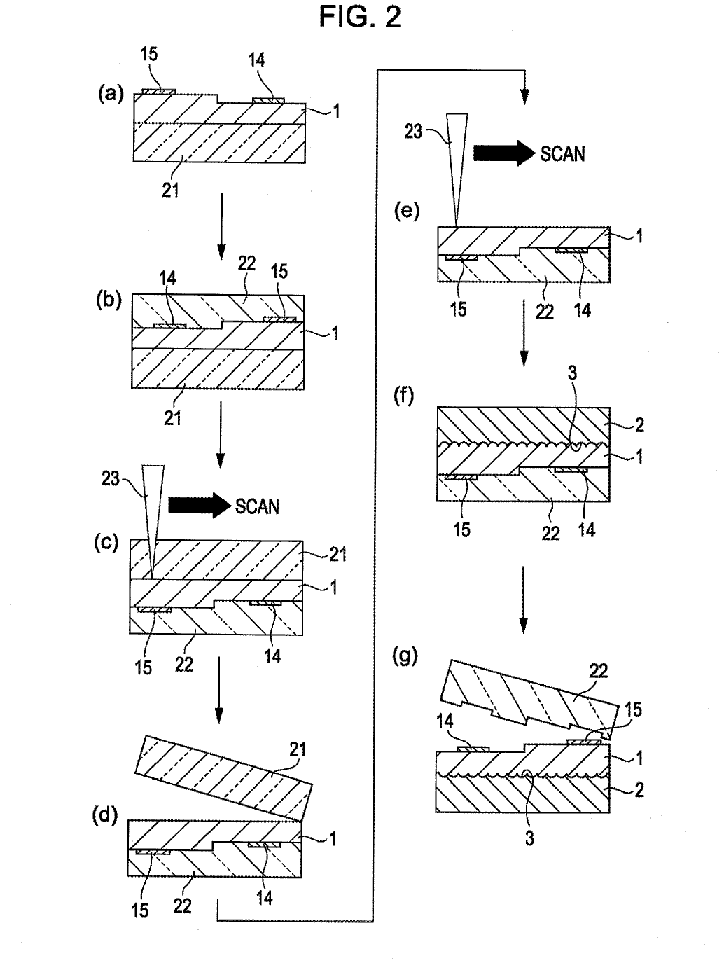

Now, an exemplary method of manufacturing the semiconductor light-emitting element according to an embodiment of the present invention is described with reference to FIG. 2. FIG. 2 is a flowchart showing a manufacturing procedure of the semiconductor light-emitting element according to the embodiment of the present invention.

First, referring to FIG. 2(a), the semiconductor layer 1 including the light-emitting layer 12, n-electrode 14, and p-electrode 15, though not illustrated, is formed on a surface of a sapphire substrate 21 by a known method. Next, referring to FIG. 2(b), a support substrate 22 made of, for example, a glass plate, temporarily supports the upper side of the semiconductor layer 1. Then, referring to FIG. 2(c), an excimer laser 23 with a wavelength of 308 or 248 nm is focused on an interface between the semiconductor layer 1 and the sapphire substrate 21. While the condition is maintained, the excimer laser 23 scans the semiconductor layer 1 in a plane direction. Accordingly, an interface portion between the semiconductor layer 1 and the sapphire substrate 21 is melted, and referring to FIG. 2(d), the sapphire substrate 21 is separated from the semiconductor layer 1. Then, referring to FIG. 2(e), the excimer laser 23 with the wavelength of 308 or 248 nm is focused on the exposed surface of the semiconductor layer 1 again. While this condition is maintained, the excimer laser 23 scans the semiconductor layer 1 in the plane direction. Hence, the surface of the semiconductor layer 1 is melted again. It is to be noted that the process may be omitted if a surface portion of the semiconductor layer 1 is uniformly and sufficiently melted after the sapphire substrate 21 is separated. While the surface portion of the semiconductor layer 1 is melted, referring to FIG. 2(f), an irregular surface of the holding substrate 2 with the projections/depressions or stripe grooves 3 formed in a surface of the holding substrate 2 is pressed against the semiconductor layer 1, so that the projections/depressions or stripe grooves 3 formed in the holding substrate 2 are transferred onto the surface portion of the semiconductor layer 1. It is to be noted that the pressing of the holding substrate 2 may be preferably performed in vacuum in order to prevent gas bubbles from being mixed. Finally, referring to FIG. 2(g), the support substrate 22 is separated, and a semiconductor light-emitting element is obtained as a product.

In the method of manufacturing the semiconductor light-emitting element according to the embodiment, while the surface portion is melted, the holding substrate 2 with the projections/depressions or stripe grooves 3 is pressed against the surface portion of the semiconductor layer 1, so that the projections/depressions or stripe grooves 3 for light scattering are transferred onto the interface between the semiconductor layer 1 and the holding substrate 2. Hence, the crystal quality of the semiconductor layer 1 is not adversely affected, and a high-quality semiconductor light-emitting element can be constantly manufactured.

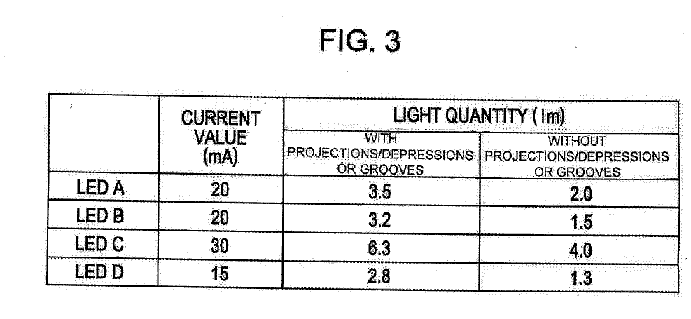

A sample with the projections/depressions or stripe grooves 3 for light scattering and a sample without the projections/depressions or stripe grooves 3 were fabricated for each of semiconductor light-emitting elements (LEDs) A and B with a rated current value of 20 mA and an emission wavelength of 460 nm, a semiconductor light-emitting element C with a rated current value of 30 mA and an emission wavelength of 460 nm, and a semiconductor light-emitting element D with a rated current value of 15 mA and an emission wavelength of 460 nm. The light quantity of light output from each of the semiconductor light-emitting elements was measured. As a result, referring to FIG. 3, the light quantities of the semiconductor light-emitting elements A and B with the rated current value of 20 mA increased by a rate ranging from 75% to 113%, the light quantity of the semiconductor light-emitting element C with the rated current value of 30 mA increased by 58%, and the light quantity of the semiconductor light-emitting element D with the rated current value of 15 mA increased by 115%. Thus, it was found that the semiconductor light-emitting elements according to the example of the present invention be markedly effective for enhancement of the light extraction efficiency.

1. A method of manufacturing a semiconductor light-emitting element, the method comprising the steps of:
forming a semiconductor layer on a surface of a sapphire substrate, the sapphire substrate having smooth surfaces;
mounting a support substrate on the semiconductor layer, the support substrate temporarily supporting the semiconductor layer;
melting a surface portion of the semiconductor layer and separating the sapphire substrate from the semiconductor layer at an interface between the sapphire substrate and the semiconductor layer, thereby exposing the semiconductor layer;
while the exposed surface portion of the semiconductor layer is melted, pressing the holding substrate against the surface portion of the semiconductor layer, the holding substrate being transparent to light emitted from the semiconductor layer, thereby transferring projections/depressions or stripe grooves formed in the holding substrate onto the surface portion of the semiconductor layer; and
separating the support substrate from the semiconductor layer at an interface between the semiconductor layer and the support substrate.

2. The method of manufacturing the semiconductor light-emitting element according to claim 1, wherein the holding substrate is an amorphous inorganic dielectric.

3. The method of manufacturing the semiconductor light-emitting element according to claim 1, wherein the pressing of the holding substrate against the semiconductor layer is performed in vacuum.
